(19) United States
(12) Patent Application Publication
(10) Pub. No.: US 2014/0079222 A1
(43) Pub. Date: Mar. 20, 2014

(54) RESTORATION OF HIGH FREQUENCIES BY FREQUENCY TRANSLATION

(71) Applicant: Justin Lamar Allen, Mesa, AZ (US)

(72) Inventor: Justin Lamar Allen, Mesa, AZ (US)

(73) Assignee: QUICKFILTER TECHNOLOGIES, LLC, Allen, TX (US)

(21) Appl. No.: 13/620,631

(22) Filed: Sep. 14, 2012

(51) Int. Cl. H03G 5/00; H04R 5/00

(52) U.S. Cl. 381/17; 381/98

(57) ABSTRACT

A method, circuit and article of manufacture for restoring high-frequency content in a first signal includes down-sampling the first signal by a factor to give a second signal; up-sampling the second signal by the same factor to give a third signal; low-pass filtering the third signal to give a fourth signal; high-pass filtering the fourth signal to give a fifth signal; and, adding the fifth signal to the first signal.

### BACKGROUND

1. Technical Field

The present disclosure relates to signal enhancement, and in particular, to methods and systems for restoring high frequency components to an audio stream.

2. Background

It is known to enhance signals, especially audio signals, by amplifying one frequency range more strongly than another frequency range. In this way, it is possible to boost higher or lower frequencies which are typically perceived to be less loud than mid-range frequencies. It has been found, however, that many transducers are not capable of rendering high and low frequencies at an appreciable sound level without introducing distortion. This is especially a problem for low audio or bass frequencies.

It has been proposed to enhance an audio signal by adding harmonics of the bass frequencies. The enhancement signals are produced by a harmonics generator and then added to the amplified original audio signal. The added harmonics are perceived as an amplified bass signal. It has further been proposed to add sub-harmonics of the audio signal to create the impression of bass enhancement. Similar techniques have been used for enhancement of high frequencies.

Although adding harmonics or sub-harmonics provides a significant improvement of the audio signal, some listeners are not entirely content with the resulting enhanced audio signals, as in some audio signals these techniques may introduce artifacts. What is needed is a way to overcome these and other problems of the prior art and to provide a system and method for enhancing audio signals which introduce substantially no artifacts or distortion.

### DRAWINGS

FIG. 1 is a block diagram of an embodiment of the method.

FIG. 2 is a graphical representation of a signal down-sampled by two.

FIG. 3 is a graphical representation of a signal up-sampled by two.

FIG. 4 is a graphical representation of a signal low-pass filtered after the up- and down-sampling operations.

FIG. 5 is a graphical representation of a signal high-pass filtered after the previous step.

FIG. 6 is a graphical representation of the signal resulting when the previously-processed signals are added to the original audio stream.

### DESCRIPTION

The system and method disclosed here attempts to restore any high frequency content that has been lost due to audio compression or other processing. The system can also be used to emphasize high frequency content to compensate for loud speaker performance, or merely because of system designer or end user preference. In summary, the system and method uses frequency translation to move audio content from the low frequency range to the high frequency range. Aliasing in the frequency domain is used to do the frequency translation. No new content is generated in the frequency-translation method as in the harmonics generation method.

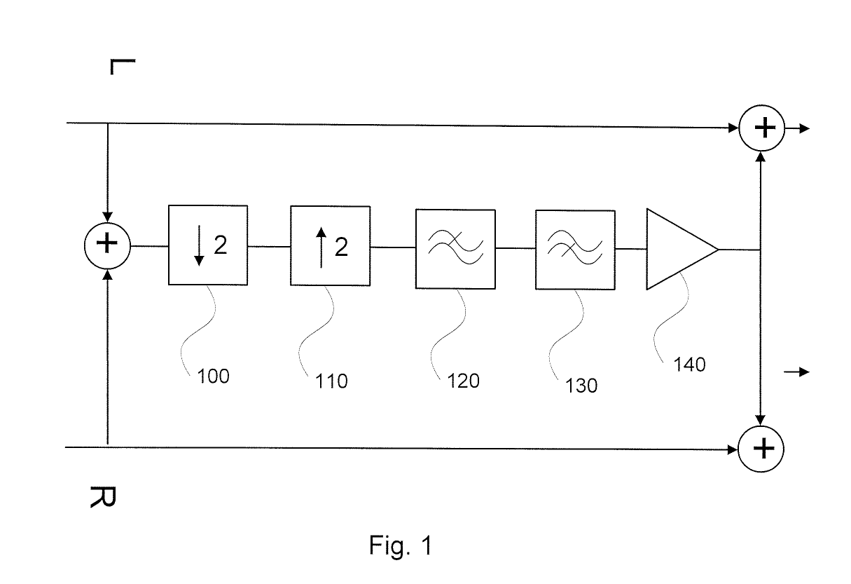

The block diagram for an embodiment is shown in FIG. 1. There are five processing blocks shown in FIG. 1. The down-sample by two (100) and up-sample by two (110) introduce aliasing into the upper frequency bands. The low-pass filter (120), high-pass filter (130), and gain (140) control the amount of aliased frequency energy that is added back into the full band audio.

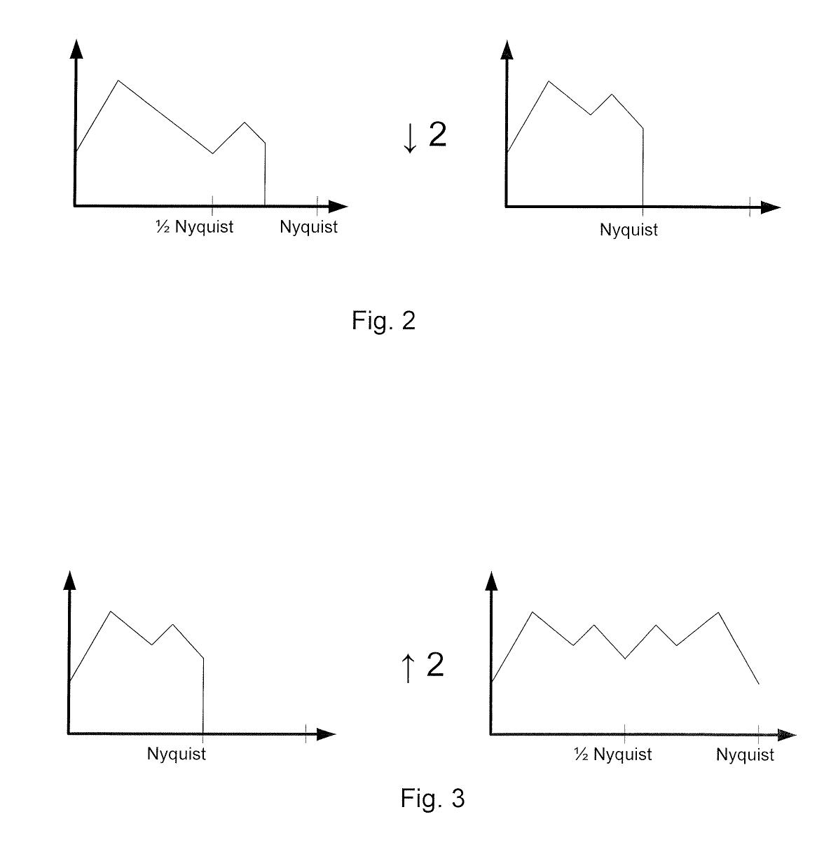

The down-sample by two block (100) aliases any content above half the Nyquist rate down to below half the Nyquist rate, where the Nyquist rate is the sampling rate equal to or greater than twice the highest frequency component in the analog signal. The down-sample block (100) also allows for the up-sample by two (110) to occur later, while still maintaining the same overall sample rate. For all examples that follow, we assume a sample rate of 48 kHz, although any other appropriate sample rate could be used. The down-sample block (100) causes all the energy above 12 kHz to be aliased below 12 kHz. The frequencies are mirrored around 12 kHz. So, for example, an energy that was at 13 kHz before down sampling, is aliased to 11 kHz after down sampling. Any energy at 15 kHz is aliased to 9 kHz, etc. FIG. 2 shows this aliasing effect graphically.

The up-sample by two block (110) translates the low frequencies to higher frequencies. When the sample rate is doubled by inserting zeros in between each sample, the Nyquist frequency is doubled and all the energy that was below the original Nyquist frequency is mirrored to also reside above the original Nyquist frequency. For example, using a sample rate of 48 kHz, the energy at 5 kHz will be mirrored to 19 kHz after up sampling. The energy at 10 kHz will be mirrored to 14 kHz, etc. FIG. 3 illustrates this mirroring of the energy that occurs when the signal is up-sampled.

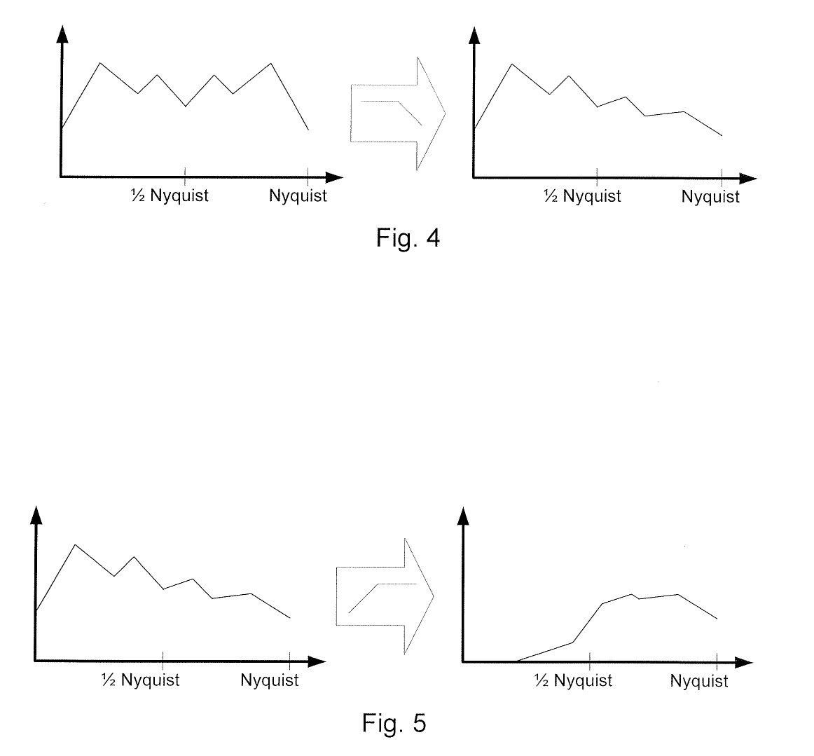

After the up-sample by two (110), a filter (120), preferably a low-pass filter, is used to shape the higher frequencies. The energy spectrum of audio typically slopes down from low to high frequencies. After the aliasing that is done in the first two steps, the audio spectrum looks more like a smile curve, sloping down from the low to mid frequencies then back up again to the high frequencies. In order to shape the spectrum correctly for audio, a low order low-pass filter (120) is used. This filter has a cut-off of one half of Nyquist. That would be 12 kHz in the examples that have been given. The filter should be first or second order. FIG. 4 illustrates the effect of low-pass filtering the aliased spectrum. This filter (120) does not have to be a low-pass filter; it can be any filter that shapes the magnitude response, such as a band-pass filter, differentiator, or whatever the designer wishes to shape the response.

The method can be implemented in a digital signal processor. The up-sample and down-sample can be done in one step by replacing every other input sample by zero. The shaping filter is implemented using a second-order IIR low-pass filter. The isolation is done by using a second-order high-pass filter. The newly-created signal is gained by a predetermined factor and added back to the original signal.

After the high frequencies have been translated and shaped they need to be isolated so that they can be added to the original spectrum. A high-pass filter (130) accomplishes this step. The cut-off of the high-pass filter (130) should be the point where the input audio has no energy. In the example given here that would be about 15 kHz. It will be difficult in general to anticipate the cut-off frequency needed. Different audio compression algorithms filter the high frequencies at different points. The cut-off point will also depend on the bit-rate at which the audio is encoded. To mitigate the effects of not filtering at the right cut-off frequency, a low order high-pass filter (130) should be used. A second-order filter is a good compromise. The cut-off for this filter (130) should be set at the highest frequency of the input with significant energy. For example, if the input is an MP3 file with no significant energy above 16 kHz, the this filter's cut-off should be set at 16 kHz. FIG. 5 illustrates the effect of high-pass filtering on the spectrum. This filter (130) can be implemented with any order and any filter topology.

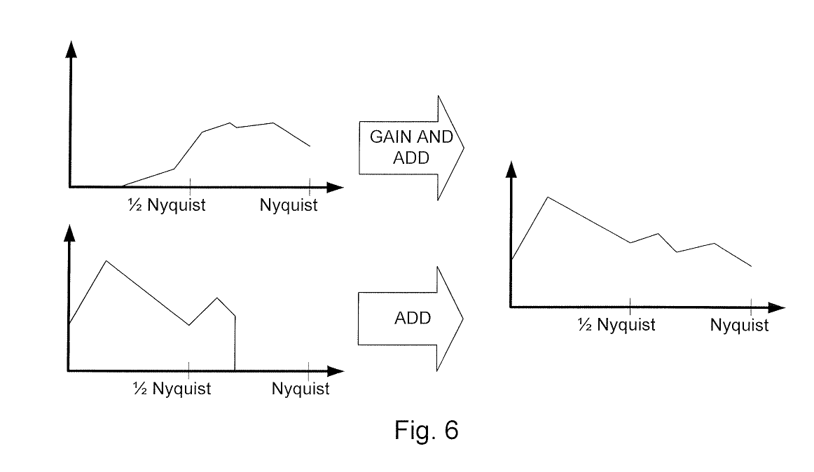

The final stage (140) before adding the new high-frequency content to the original audio is to increase the gain of the high frequencies. This gain (140) should preferably be between one and six. To simply restore lost content a lower gain should be used. To also add emphasis to the high frequencies, a high gain should be used. FIG. 6 illustrates the effect of gaining the high frequencies and adding them to the original audio.

None of the description in this application should be read as implying that any particular element, step, or function is an essential element which must be included in the claim scope; the scope of patented subject matter is defined only by the allowed claims. Moreover, none of these claims are intended to invoke paragraph six of 35 U.S.C. Section 112 unless the exact words “means for” are used, followed by a gerund. The claims as filed are intended to be as comprehensive as possible, and no subject matter is intentionally relinquished, dedicated, or abandoned.

I claim:

1. A method for restoring high-frequency content in a first signal, comprising:
down-sampling the first signal by a factor to give a second signal;
up-sampling the second signal by the same factor to give a third signal;
filtering the third signal to give a fourth signal;
high-pass filtering the fourth signal to give a fifth signal; and, adding the fifth signal to the first signal.

2. The method of claim 1 where the sampling factor is two.

3. The method of claim 1 where the fifth signal is amplified before being added to the original signal.

4. The method of claim 3 where the fifth signal is amplified by a factor between one and six.

5. The method of claim 1 where the first signal comprises left and right signals, and the left and right signals are added together before down-sampling by the factor.

6. The method of claim 5 where the fifth signal is added to the left and right signals equally.

7. The method of claim 1 where the filtering of the third signal is low-pass filtering.

8. A circuit for restoring high-frequency content in a first signal, comprising:
a down-sampler for down-sampling the first signal by a factor to give a second signal;
an up-sampler connected to the down-sampler for up-sampling the second signal by the same factor to give a third signal;
a first filter connected to the down-sampler for filtering the third signal to give a fourth signal;
a high-pass filter connected to the low-pass filter for high-pass filtering the fourth signal to give a fifth signal;
an adder for summing the fifth signal with the first signal.

9. The circuit of claim 8 where the sampling factor is two.

10. The circuit of claim 8 further comprising an amplifier connected to the output of the high-pass filter and to the input of the adder.

11. The circuit of claim 10 where the amplifier has a gain between one and six.

12. The circuit of claim 8 where the first filter is a low-pass filter.

13. An article of manufacture comprising a computer-readable medium having computer-executable instructions for performing a method for restoring high-frequency content in a first signal, the method comprising:
down-sampling the first signal by a factor to give a second signal;
up-sampling the second signal by the same factor to give a third signal;
filtering the third signal to give a fourth signal;
high-pass filtering the fourth signal to give a fifth signal; and, adding the fifth signal to the first signal.

14. The article of manufacture of claim 13, where the sampling factor is two

15. The article of manufacture of claim 13, where the fifth signal is amplified before being added to the original signal.

16. The article of manufacture of claim 15, where the fifth signal is amplified by a factor between one and six.

17. The article of manufacture of claim 13, where the first signal comprises left and right signals, and the left and right signals are added together before down-sampling by the factor.

18. The article of manufacture of claim 17 where the fifth signal is added to the left and right signals equally.

19. The article of manufacture of claim 13 where the filtering of the third signal is low-pass filtering.
